(19) United States
(12) Patent Application Publication
(10) Pub. No.: US 2013/0076210 A1
(43) Pub. Date: Mar. 28, 2013

(54) PIEZOELECTRIC VIBRATION REED, PIEZOELECTRIC VIBRATOR, OSCILLATOR, ELECTRONIC INSTRUMENT, AND RADIO TIMEPIECE

(71) Applicant: Seiko Instruments Inc., Chiba (JP)

(72) Inventor: Takashi MINEGISHI, Chiba (JP)

(73) Assignee: SEIKO INSTRUMENTS INC., Chiba (JP)

(21) Appl. No.: 13/628,310

(22) Filed: Sep. 27, 2012

(30) Foreign Application Priority Data
Sep. 28, 2011 (JP) 2011-213018

(51) Int. Cl. H01L 41/04

(52) U.S. Cl. 310/370

(57) ABSTRACT

A piezoelectric vibration reed which is capable of inhibiting vibrations of a vibrating arm portion in the thickness direction and inhibiting the increase in CI value and a vibration leak, a piezoelectric vibrator, an oscillator, an electronic instrument, and a radio timepiece using the piezoelectric vibration reed is provided. A piezoelectric vibration reed includes: a pair of vibrating arm portions arranged side by side; groove portions formed on both main surfaces of the vibrating arm portions and extending in the Y direction (the longitudinal direction) of the vibrating arm portions; a base portion connecting the pair of vibrating arm portions; and the groove portions are each formed in the interior thereof with a rib extending from a wall surface on a −Y side (proximal end side) to a +Y side (distal end side).

### RELATED APPLICATIONS

This application claims priority under 35 U.S.C. §119 to Japanese Patent Application No. 2011-213018 filed on Sep. 28, 2011, the entire content of which is hereby incorporated by reference.

### 1. TECHNICAL FIELD

The present invention relates to a piezoelectric vibration reed, a piezoelectric vibrator, an oscillator, an electronic instrument, and a radio timepiece using the piezoelectric vibrator.

### 2. DESCRIPTION OF THE RELATED ART

In mobile phones or portable information terminal equipment, a piezoelectric vibrator using crystal or the like is employed as a timing source or a reference signal source of a time-of-day source or a control signal. Various types of the piezoelectric vibrators of this type are provided, and as one of these piezoelectric vibrators, a piezoelectric vibrator having so-called a tuning-fork-type piezoelectric vibration reed sealed in a package is known.

The fork-type piezoelectric vibration reed is a thin plate shaped crystal strip including a pair of vibration arm portions disposed side by side in the width direction and a base portion configured to integrally fixing proximal end sides of the pair of vibrating arm portions in the longitudinal direction. The piezoelectric vibration reed vibrates at a predetermined resonant frequency in the width direction so that the pair of vibrating arm portions move toward and away from each other when a voltage is applied to excitation electrodes formed on the respective vibrating arm portions.

In recent years, further downsizing of the piezoelectric vibration reed is desired in association with downsizing of mounted equipment. As a method of downsizing of the piezoelectric vibration reed while reducing the CI (Crystal Impedance) value of the piezoelectric vibration reed, there is a widely known method of forming groove portions on both main surfaces of the vibrating arm portions (for example, see JP-A-2003-92530).

The piezoelectric vibration reed described in JP-A-2003-92530 includes a base portion, a plurality of vibrating arm portions formed so as to project from the base portion, and groove portions are formed on front surface portions and back surface portions of the respective vibrating arm portions. With the formation of the groove portions, the cross-sectional shape of the vibrating arm portion taken along the direction perpendicular to the longitudinal direction thereof is substantially an H-shape.

FIG. 15 is an explanatory drawing showing a normal vibrating state of a piezoelectric vibration reed 4.

FIG. 16 is an explanatory drawing of a piezoelectric vibration reed 4 of the related art.

In FIG. 15 and FIG. 16, the width direction of the piezoelectric vibration reed 4 is expressed as an X direction, the longitudinal direction is expressed as a Y direction, and the thickness direction is expressed as a Z direction in the description. Also, in FIG. 15 and FIG. 16, the width of deflection of the vibrating arm portions 10 and 11 are exaggerated for the sake of easy-to-understand of the drawings.

When groove portions 51 are formed on the piezoelectric vibration reed 4, the surface area of the cross section taken along the direction perpendicular to the Y direction of the vibrating arm portions 10 and 11 (hereinafter, referred to as “cross-sectional area of the vibrating arm portions 10 and 11”) is smaller than that in a case where the groove portions 51 are not formed, so that the bending rigidity of the vibrating arm portions 10 and 11 in the Z direction is lowered.

Therefore, when the piezoelectric vibration reed 4 is activated, the vibrating arm portions 10 and 11 are subjected to bending vibration in the Z direction caused by lowering of the bending rigidity in the Z direction as shown in FIG. 16 in addition to the bending vibration in the normal X direction shown in FIG. 15. More specifically, there is a risk of flip-flop vibration of the first vibrating arm portion 10 and the second vibrating arm portion 11 in opposite phases in the Z direction as shown in FIG. 16. The vibrations in the Z direction of the vibrating arm portions 10 and 11 may cause an increase in a CI value and so-called a vibration leak, which is a leak of the vibrations of the piezoelectric vibration reed 4 to the outside.

### SUMMARY

Accordingly, it is an object of the invention to provide a piezoelectric vibration reed which is capable of inhibiting vibrations of the vibrating arm portion in the thickness direction and inhibiting the increase in the CI value and a vibration leak, a piezoelectric piezoelectric vibrator, an oscillator, an electronic instrument, and a radio timepiece using the piezoelectric vibration reed.

In order to solve the above-described problem, there is provided a piezoelectric vibration reed including: a pair of vibrating arm portions arranged side by side; groove portions formed on both main surfaces of the vibrating arm portions and extending along the longitudinal direction of the vibrating arm portions; a base portion connecting the pair of vibrating arm portions; wherein the groove portions are each formed in the interior thereof with a rib extending from one wall surface on either a proximal end side in the longitudinal direction and a distal end side in the longitudinal direction to the other one of the proximal end side and the distal end side.

According to the invention, the cross-sectional area of the vibrating arm portions may be increased by forming the ribs in the groove portions. Accordingly, since the high bending rigidity with respect to the thickness direction of the vibrating arm portions are secured in comparison with the related art, the vibrating arm portions are inhibited from vibrating in the thickness direction when the piezoelectric vibration reed is activated. Therefore, the piezoelectric vibration reed which can inhibit the increase in the CI value and the vibration leak is obtained.

Also, by securing the high bending rigidity of the vibrating arm portions, breakage of the vibrating arm portions may be prevented even when the piezoelectric vibration reed drops or the like and is subjected to an impact.

Preferably, the ribs extend from the wall surfaces on the proximal end side to the distal end side.

According to the invention, since the ribs extend from the wall surfaces on the proximal end side to the distal end side in the groove portions, the cross-sectional area on the proximal end sides of the vibrating arm portions may be increased. Accordingly, the high bending rigidity of the vibrating arm portions on the proximal end side may be secured, and the entire vibrating arm portions are prevented from vibrating in the thickness direction at a portion in the vicinity of a connecting portion between the proximal portion and the vibrating arm portions as a bending point. Therefore, the increase in the CI value and the vibration leak can be effectively inhibited. Also, when the piezoelectric vibration reed is subjected to an impact, since the bending rigidity at the connecting portion between the base portion and the vibrating arm portions which are susceptible to the stress is secured, the breakage of the vibrating arm portions can be prevented reliably.

Preferably, the width of the ribs on the proximal end sides of the vibrating arm portions is larger than the width of the ribs on the distal end sides of the vibrating arm portions.

According to the invention, the width of the ribs on the proximal end side of the vibrating arm portions is larger than the width of the ribs on the distal end sides of the vibrating arm portions, the cross-sectional area of the vibrating arm portions on the proximal end side can be increased. Accordingly, since the bending rigidity on the proximal end side of the vibrating arm portions can further be increased, the vibration of the vibrating arm portions in the thickness direction may further be inhibited. Also, the breakage of the vibrating arm portions may further be prevented even when the vibrating arm portions are subjected to an impact.

According to the invention, the width of the ribs on the distal end side of the vibrating arm portions is smaller than the width of the ribs on the proximal end sides of the vibrating arm portions, the cross-sectional area of the groove portions on the distal end side of the vibrating arm portions is secured to be larger than the cross-sectional area of the groove portions on the proximal end side of the vibrating arm portions. In this configuration, the distal end sides of the vibrating arm portions can be vibrated efficiently in the width direction, and hence the field efficiency is improved and the vibration property improved.

In this manner, by forming the ribs on the proximal end side of the vibrating arm portions to have a width larger than the width of the ribs on the distal end side of the vibrating arm portions, improvement of both of the bending rigidity on the proximal end side of the vibrating arm portions and the vibration characteristics of the piezoelectric vibration reed is achieved.

Preferably, the width of the groove portions on the proximal end side of the vibrating arm portions is smaller than the width of the groove portions on the distal end side of the vibrating arm portions.

According to the invention, since the width between side surfaces of the vibrating arm portions and side surfaces of the groove portions are formed to be large on the proximal end side of the vibrating arm portions, the cross-sectional area of the vibrating arm portions on the distal end side may be formed to be larger than the cross-sectional area of the vibrating arm portions on the proximal end side. Accordingly, since the bending rigidity on the proximal end side of the vibrating arm portions can further be increased, vibration of the vibrating arm portions in the thickness direction may further be inhibited. Also, breakage of the vibrating arm portions may reliably be prevented even when the vibrating arm portions are subjected to an impact. In particular, by forming the width of the groove portions on the proximal end side to be smaller than the width of the groove portions on the distal end sides while forming the width of the ribs on the proximal end side to be larger than the width of the ribs on the distal end side, the bending rigidity of the vibrating arm portions on the proximal end side can significantly be enhanced. Accordingly, the vibrations of the vibrating arm portions in the thickness direction may reliably be inhibited and the increase in the CI value and the vibration leak may reliably be inhibited.

Preferably, the width of the groove portions is constant along the longitudinal direction of the vibrating arm portions.

According to the invention, the side surfaces of the vibrating arm portions and the side surfaces of the groove portions may be arranged so as to oppose each other at a significantly short distance. Accordingly, when a voltage is applied on electrodes (excitation electrodes) formed respectively on the side surfaces of the vibrating arm portions and the side surfaces of the groove portions, an electrical field is formed efficiently between the side surfaces of the vibrating arm portions and the side surfaces of the groove portions, so that the vibrating arm portions can be vibrated efficiently in the width direction. In particular, while forming the width of the ribs on the proximal end side to be larger than the width of the ribs on the distal end side and forming the width of the groove portions to be constant along the longitudinal direction of the vibrating arm portions, the piezoelectric vibration reed having with little loss may be formed while enhancing the bending rigidity of the vibrating arm portions on the proximal end side.

A piezoelectric vibrator according to the invention includes the piezoelectric vibration reed described above.

According to the invention, since the piezoelectric vibration reed which is capable of inhibiting the increase in the CI value or the vibration leak is provided, the piezoelectric vibrator presenting high efficiency with small power consumption is provided.

An oscillator according to the invention includes the above-described piezoelectric vibrator electrically connected to an integrated circuit as an oscillator.

An electronic instrument according to the invention includes the above-described piezoelectric vibrator electrically connected to a clocking unit.

A radio timepiece according to the invention includes the above-described piezoelectric vibrator electrically connected to a filter portion.

According to the invention, the high performance oscillator, the electronic instrument and the radio timepiece presenting high efficiency with small power consumption are provided.

According to the invention, the cross-sectional area of the vibrating arm portions may be increased by forming the ribs in the groove portions. Accordingly, since high bending rigidity with respect to the vibrating arm portions in the thickness direction is secured in comparison with the related art, the vibrating arm portions is prevented from vibrating in the thickness direction when the piezoelectric vibration reed is activated. Therefore, the piezoelectric vibration reed which can inhibit the increase in the CI value and the vibration leak is obtained.

Also, by securing the high bending rigidity of the vibrating arm portions, breakage of the vibrating arm portions may be prevented even when the piezoelectric vibration reed drops or the like and is subjected to an impact.

### BRIEF DESCRIPTION OF THE DRAWINGS

FIG. 1 is a plan view of a piezoelectric vibration reed;

FIG. 2 is an enlarged drawing of groove portions;

FIG. 3 is a cross-sectional view taken along the line A-A in FIG. 1;

FIG. 4 is a cross-sectional view taken along the line B-B in FIG. 1;

FIG. 5 is an explanatory drawing of a drive level property;

FIG. 6 is an explanatory drawing showing a first modification of the embodiment;

FIG. 7 is an explanatory drawing of a second modification of the embodiment;

FIG. 8 is an appearance perspective view of a piezoelectric vibrator;

FIG. 9 is a plan view showing a configuration of the interior of the piezoelectric vibrator in a state in which a lid substrate is removed;

FIG. 10 is a cross-sectional view taken along the line C-C in FIG. 9;

FIG. 11 is an exploded perspective view of the piezoelectric vibrator shown in FIG. 8;

FIG. 12 is a drawing showing a configuration of an embodiment of an oscillator;

FIG. 13 is a drawing showing a configuration of an embodiment of an electronic instrument;

FIG. 14 is a drawing showing a configuration of an embodiment of a radio timepiece; and

FIG. 15 is an explanatory drawing showing a normal vibrating state of a piezoelectric vibration reed; and

FIG. 16 is an explanatory drawing of the piezoelectric vibration reed of the related art.

### DESCRIPTION OF THE PREFERRED EMBODIMENTS

### (Piezoelectric Vibration Reed)

Referring now to the drawings, the piezoelectric vibration reed according to an embodiment will be described below.

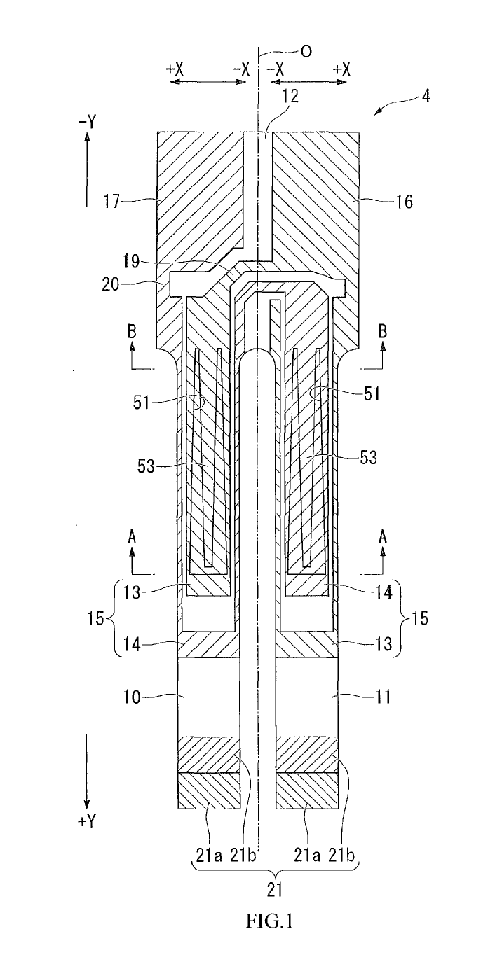

FIG. 1 is a plan view of a piezoelectric vibration reed 4.

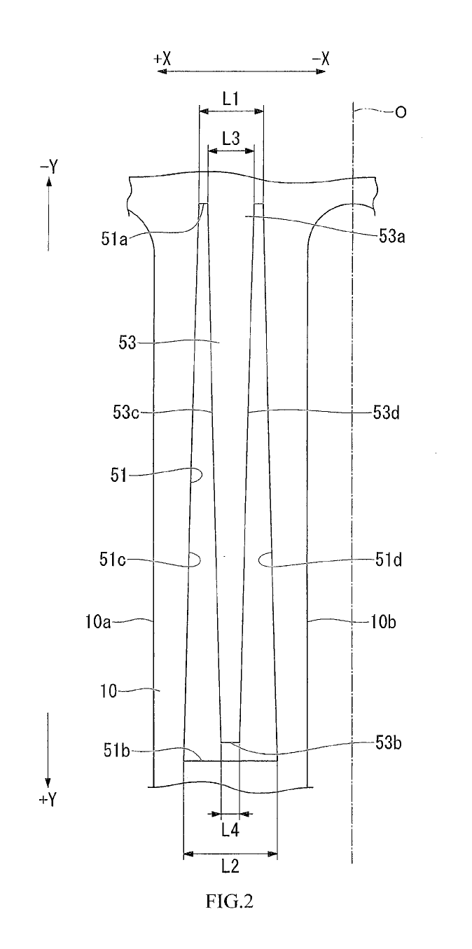

FIG. 2 is an enlarged view of groove portions 51. In FIG. 2, illustration of excitation electrodes 13 and 14 described later is omitted for the sake of easy understanding.

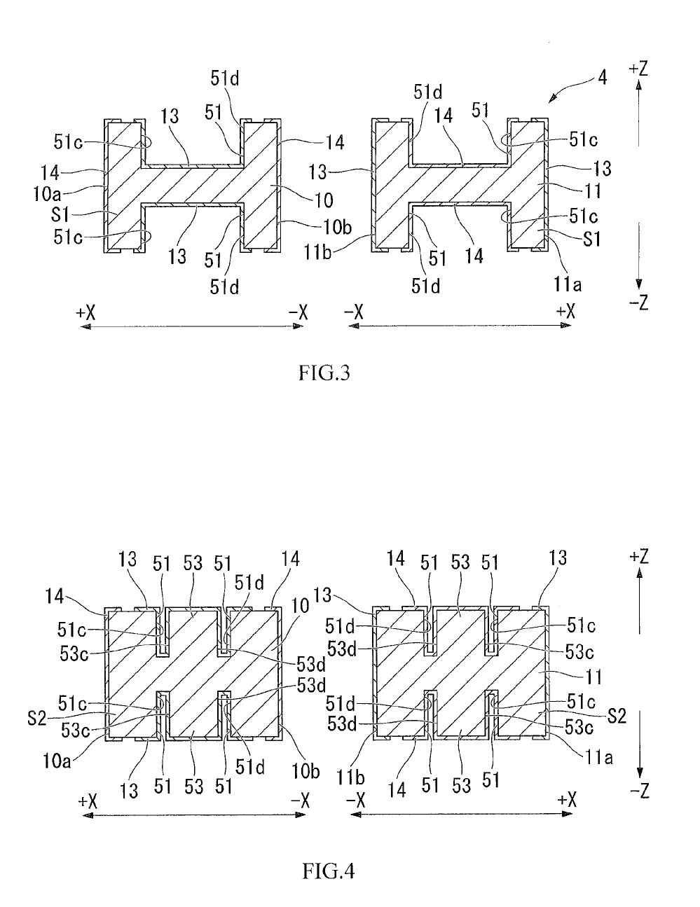

FIG. 3 is a cross-sectional view of the groove portions 51 taken along the line A-A in FIG. 1.

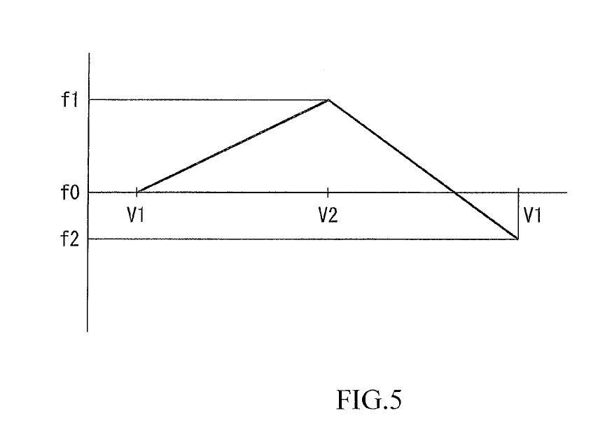

FIG. 4 is a cross-sectional view of the groove portions 51 taken along the line B-B in FIG. 1.

In the following description, the width direction in which vibrating arm portions 10 and 11 are arranged side by side is expressed as an X direction (see FIG. 1), a central axis in the X direction is expressed as 0, an inside of the piezoelectric vibration reed 4 is expressed as a −X side, and an outside of the same is expressed as a +X side in the description. The longitudinal direction of the piezoelectric vibration reed 4 is expressed as a Y direction (see FIG. 1), a proximal end side is expressed as a −Y side, and a distal end side is expressed as a +Y side in the description. The direction of the thickness of the piezoelectric vibration reed 4 is expressed as a Z direction (see FIG. 3), one side (upper side in FIG. 3) is expressed as a +Z side, and the other side (lower side in FIG. 3) is expressed as a −Z side in the description.

As shown in FIG. 1, the piezoelectric vibration reed 4 is the turning-fork-type piezoelectric vibration reed 4 formed of a piezoelectric material such as crystal, lithium tantalate, or lithium niobate.

The piezoelectric vibration reed 4 includes a pair of the vibrating arm portions 10 and 11 (first vibrating arm portion 10 and a second vibrating arm portion 11) arranged in parallel, and a base member 12 integrally fixing the −Y sides of the pair of vibrating arm portions 10 and 11. The piezoelectric vibration reed 4 is configured to vibrate in the X direction so that the vibrating arm portions 10 and 11 move toward and away from each other when a predetermined voltage is applied.

The pair of vibrating arm portions 10 and 11 extend in the Y direction along the central axis O and are formed in substantially parallel to each other in the X direction. The groove portions 51 extending along the Y direction of the vibrating arm portions 10 and 11 are formed on a +Z side surface and a −Z side surface (both main surfaces) of the vibrating arm portions 10 and 11. The groove portion 51 formed on the first vibrating arm portion 10 and the groove portion 51 formed on the second vibrating arm portion 11 have the same shape. Therefore, in the description given below, the groove portion 51 formed on the first vibrating arm portion 10 will be described, and the description of the groove portion 51 formed on the second vibrating arm portion 11 will be omitted.

### (Groove Portion)

As shown in FIG. 2, the groove portion 51 is formed on the first vibrating arm portion 10. A −Y side wall surface 51a of the groove portion 51 is arranged in the vicinity of the connecting portion between the first vibrating arm portion 10 and the base member 12. A +Y side wall surface 51b of the groove portion 51 is arranged at a substantially center of the first vibrating arm portion 10 in the Y direction. In other words, the groove portion 51 is formed along the Y direction in a range from a portion in the vicinity of a connecting portion between the first vibrating arm portion 10 and the base member 12 to the substantially center of the first vibrating arm portion 10 in the Y direction at a predetermined depth.

The groove portion 51 is formed so that a width L1 of the −Y side wall surface 51a is smaller than a width L2 of the +Y side wall surface 51b. More specifically, a +X side surface 51c of the groove portion 51 is inclined to the −X side at a predetermined angle and a −X side surface 51d is inclined to the +X side at a predetermined angle from the +Y side to the −Y side. Accordingly, the width of the groove portion 51 is formed to be narrowed in a gradual tapered shape from the +Y side to the −Y side.

A rib 53 is formed at a substantially center in the X direction in the groove portion 51. A −Y side end portion 53a of the rib 53 is arranged in the vicinity of the connecting portion between the first vibrating arm portion 10 and the base member 12, and is connected to the −Y side wall surface 51a of the groove portion 51. A +Y side end portion 53b of the rib 53 is arranged on the −Y side with respect to the +Y side wall surface 51b of the groove portion 51, and is apart from the +Y side wall surface 51b of the groove portion 51. In other words, the rib 53 is formed along the Y direction in a range from the −Y side wall surface 51a in the groove portion 51 to the −Y side with respect to the +Y side wall surface 51b of the groove portion 51.

The rib 53 is formed so that a width L3 of the −Y side end portion 53a is larger than a width L4 of the +Y side end portion 53b. More specifically, a +X side surface 53c of the rib 53 is inclined to the +X side at a predetermined angle and a −X side surface 53d is inclined to the −X side at a predetermined angle from the +Y side to the −Y side. Accordingly, the width of the rib 53 is formed to be increased in a gradual tapered shape from the +Y side to the −Y side.

As described above, the +Y side end portion 53b of the rib 53 is apart from the +Y side wall surface 51b of the groove portion 51. Therefore, as in the cross-sectional view in FIG. 3 taken along the line A-A in FIG. 1, the rib 53 is not provided in the groove portion 51 on the +Y side of the groove portion 51. Consequently, the cross-sectional area of the groove portion 51 in the A-A cross-section is increased, and a cross-sectional area S1 of each of the vibrating arm portions 10 and 11 is reduced.

In contrast, the −Y side end portion 53a (see FIG. 2) of the rib 53 is connected to the −Y side wall surface 51a (see FIG. 2) of the groove portion 51. Therefore, as in the cross-sectional view in FIG. 4 taken along the line B-B in FIG. 1, the rib 53 is provided in the groove portion 51 on the −Y side of the groove portion 51. In addition, the width of the groove portion 51 is narrowed from the +Y side to the −Y side, and the width of the rib 53 is increased from the +Y side to the −Y side. Consequently, the cross-sectional area of the groove portion 51 in the B-B cross-section is very small, and a cross-sectional area S2 of each of the vibrating arm portions 10 and 11 is increased.

In this manner, by setting the cross-sectional area S2 on the −Y side of the vibrating arm portions 10 and 11 to be large, high bending rigidity of the vibrating arm portions 10 and 11 on the −Y side is secured. Accordingly, the bending vibration of the vibrating arm portions 10 and 11 in the Z direction about an axis along the X direction is inhibited in the vicinity of the connecting portion between the base member 12 and the vibrating arm portions 10 and 11. Therefore, vibration of the entire portions of the vibrating arm portions 10 and 11 in the Z direction is inhibited when the piezoelectric vibration reed 4 is activated.

The width of the ribs 53 on the +Y side of the vibrating arm portions 10 and 11 is formed to be smaller than the width of the ribs 53 on the −Y side of the vibrating arm portions 10 and 11. Therefore, the cross-sectional area of the groove portions 51 on the +Y side is larger than that of the groove portions 51 on the −Y side. In this configuration, the +Y sides of the vibrating arm portions 10 and 11 can be vibrated efficiently in the X direction, and hence the field efficiency is improved and the vibrational property are improved.

In this manner, by forming the ribs 53 on the −Y side of the vibrating arm portions 10 and 11 to have a width larger than the width of the ribs 53 on the +Y side of the vibrating arm portions 10 and 11, improvement of both of the bending rigidity on the −Y side of the vibrating arm portions 10 and 11 and the vibrational property of the piezoelectric vibration reed 4 are achieved.

FIG. 5 is an explanatory drawing of the drive level characteristics.

The fact that the bending rigidity of the vibrating arm portions 10 and 11 affects the drive level characteristics of the piezoelectric vibration reed 4 are generally known. The drive level characteristics here mean variability characteristics of the vibrational frequency with respect to the variations of the drive voltage.

More specifically, as shown in FIG. 5, when the voltage to be applied to the piezoelectric vibration reed 4 is increased from V1 to V2, the frequency increases from f0 to f1. Then, when the voltage to be applied to the piezoelectric vibration reed 4 is returned from V2 to V1 again, the frequency does not return from f1 to f0 frequency, and becomes a value of f2 which is lower than f0. The characteristics of a variation value Δf (the difference between f0 and f2) of the vibrational frequency is referred to as drive level characteristics. It can be said that the smaller the variation of Δf, the better the drive level characteristics are.

In this embodiment, since the cross-sectional surface area S2 on the −Y side of each of the vibrating arm portions 10 and 11 is larger, high bending rigidity on the −Y side of the vibrating arm portions 10 and 11 can be secured. Accordingly, when the piezoelectric vibration reed 4 is activated, the deflection of the vibrating arm portions 10 and 11 in the vicinity of the connecting portion between the base member 12 and the vibrating arm portions 10 and 11 is inhibited. Therefore, the piezoelectric vibration reed 4 having the preferable drive level characteristics is obtained.

### (Excitation Electrodes)

As shown in FIG. 1, the piezoelectric vibration reed 4 described above includes excitation electrodes 15 formed of the pair of vibrating arm portions 10 and 11 and each including the first excitation electrodes 13 and the second excitation electrodes 14 which vibrate the pair of vibrating arm portions 10 and 11, and mount electrodes 16 and 17 electrically connected to the first excitation electrodes 13 and the second excitation electrodes 14.

The excitation electrodes 13 and 14 are formed on the main surfaces of the pair of vibrating arm portions 10 and 11. For example, the excitation electrodes 13 and 14 are formed of a monolayer conductive film such as chrome (Cr). The excitation electrodes 13 and 14 are electrodes which vibrate the pair of vibrating arm portions 10 and 11 at a predetermined resonant frequency in the X direction so as to move toward or away from each other when a voltage is applied.

A pair of excitation electrodes 13 and 14 are formed by being patterned on the surfaces of the pair of vibrating arm portions 10 and 11 in a state of being electrically disconnected, respectively.

More specifically, the first excitation electrodes 13 are formed mainly in the groove portions 51 and outer surfaces of the ribs 53 of the first vibrating arm portion 10 and on a +X side surface 11a and a −X side surface 11b of the second vibrating arm portion 11 (see FIG. 4). Also, the second excitation electrodes 14 are formed mainly in the groove portions 51 and the outer surfaces of the ribs 53 of the second vibrating arm portion 11 and on a +X side surface 10a and a −X side surface 10b of the first vibrating arm portion 10 (see FIG. 4).

### (Mount Electrode)

As shown in FIG. 1, the base member 12 is formed with a pair of mount electrodes 16 and 17 with the central axis O interposed therebetween. The mount electrodes 16 and 17 are laminated films including chrome and gold, and is each formed by forming a chrome film presenting good adhesiveness with respect to crystal as a base layer and then forming a gold thin film on the surface thereof as a top layer. However, the invention is not limited thereto, and it is also possible to form a base layer using chrome and Nichrome for example, and then form a gold thin film further on the surface as a top layer.

### (Drawing Electrode)

The base member 12 is formed with drawn electrodes 19 and 20 configured to electrically connect the excitation electrodes 13 and 14 and the mount electrodes 16 and 17 respectively.

The drawn electrode 19 connects the mount electrode 16 and the first excitation electrode 13 formed on the first vibrating arm portion 10, and is formed so as to extend across the central axis O.

The drawn electrode 20 connects the mount electrode 17 and the second excitation electrode 14 formed on the first vibrating arm portion 10, and is formed so as to extend along the Y direction on the +X side of the base member 12.

The drawn electrodes 19 and 20 are formed of a monolayer film of chrome, which is the same material as the base layers of the mount electrodes 16 and 17. Accordingly, the drawn electrodes 19 and 20 may be formed simultaneously with the film formation of the basic layers of the mount electrodes 16 and 17. However, the invention is not limited thereto, and for example, the drawn electrodes 19 and 20 may be formed of nickel, aluminum, or titanium.

The vibrating arm portions 10 and 11 are formed with weight metal films 21 including a coarse adjustment film 21a and a fine adjustment film 21b for adjusting the vibration to fall within a range of a predetermined frequency (frequency adjustment) at distal end portions thereof. By adjusting the frequency using the weight metal film 21, the frequencies of the pair of vibrating arm portions 10 and 11 may be adjusted to fall within a range of the nominal frequency of the device.

### (Effect of Embodiment)

According to the embodiment, the cross-sectional area of the vibrating arm portions 10 and 11 may be increased by forming the ribs 53 in the groove portions 51. In particular, the ribs 53 in the embodiment extend from the −Y side to the +Y side of the groove portions 51. In addition, the width of the groove portions 51 on the −Y side is formed to be smaller than the width of the groove portions 51 on the +Y side while forming the width of the ribs 53 on the −Y side to be larger than the width of the ribs 53 on the +Y side. Therefore, on the −Y side of each of the vibrating arm portions 10 and 11, the width of the +X side surface 51c of the groove portion 51 and the +X side surface 53c of the rib 53, and the width of the −X side surface 51d of the groove portion 51 and the −X side surface 53d of the rib 53 are formed to be small. Therefore, the cross-sectional area on the −Y side of the vibrating arm portions 10 and 11 may be formed to be larger than the cross-sectional area on the +Y side of the vibrating arm portions 10 and 11 (see FIG. 3 and FIG. 4). Accordingly, high bending rigidity of the vibrating arm portions 10 and 11 with respect to the Z direction may be secured in comparison with the related art. Therefore, the piezoelectric vibration reed 4 which is capable of inhibiting the vibration of the vibrating arm portions 10 and 11 in the Z direction when the piezoelectric vibration reed 4 is activated, and inhibiting the increase in the CI value and the vibration leak is obtained.

Also, by securing the high bending rigidity of the vibrating arm portions 10 and 11, breakage of the vibrating arm portions 10 and 11 may be prevented even when the piezoelectric vibration reed 4 drops or the like and is subjected to an impact.

### (First Modification of Embodiment)

Subsequently, a first modification of the embodiment will be described.

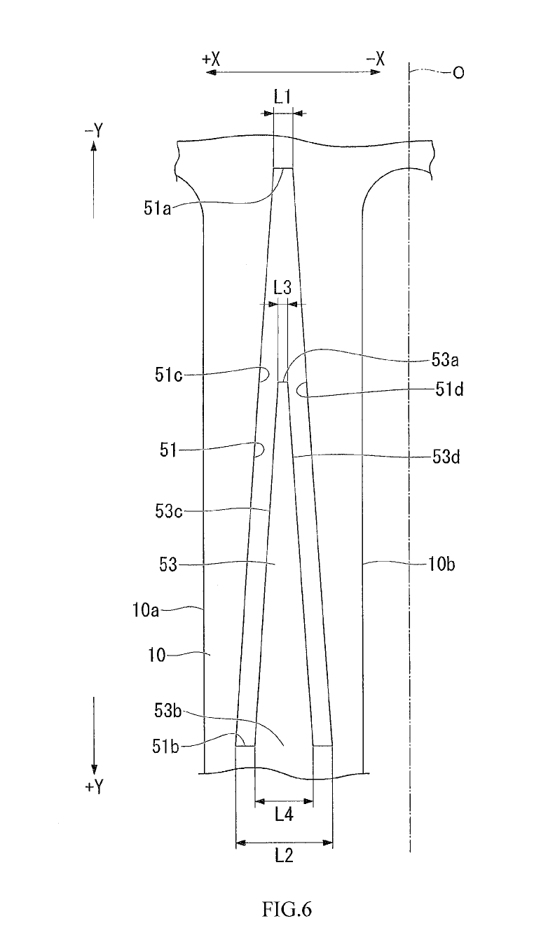

FIG. 6 is an explanatory drawing showing the first modification of the embodiment.

In the embodiment described above, the −Y side end portion 53a of the rib 53 is connected to the −Y side wall surface 51a of the groove portion 51 and is formed to extend from the −Y side to the +Y side (see FIG. 2). In contrast, the first modification is different from the embodiment in that the +Y side end portion 53b of the rib 53 is connected to the +Y side wall surface 51b of the groove portion 51 and is formed to extend from the +Y side to the −Y side as show in FIG. 6. The description of the components same as the embodiment will be omitted.

### (Groove Portion)

As shown in FIG. 6, the groove portion 51 is formed on the first vibrating arm portion 10. The groove portion 51 is formed so that the width L1 of the −Y side wall surface 51a is smaller than the width L2 of the +Y side wall surface 51b. The width L1 of the −Y side wall surface 51a of the groove portion 51 is formed to be smaller the width L1 (see FIG. 2) of the −Y side wall surface 51a of the groove portion 51 in the embodiment.

The rib 53 is formed at the substantially center in the X direction in the groove portion 51. The −Y side end portion 53a of the rib 53 is arranged on the +Y side of the connecting portion between the first vibrating arm portion 10 and the base member 12, and is apart from the −Y side wall surface 51a of the groove portion 51. The +Y side end portion 53b of the rib 53 is connected to the +Y side wall surface 51b of the groove portion 51. In other words, the rib 53 is formed along the Y direction over a range from the +Y side wall surface 51b in the groove portion 51 to the +Y side of the connecting potion between the first vibrating arm portion 10 and the base member 12.

The rib 53 is formed so that the width L3 of the −Y side end portion 53a is smaller than the width L4 of the +Y side end portion 53b corresponding to the shape of the groove portion 51. More specifically, the +X side surface 53c of the rib 53 is inclined to the −X side at a predetermined angle and the −X side surface 53d is inclined to the +X side at a predetermined angle from the +Y side to the −Y side. Accordingly, the width of the rib 53 is formed to be smaller in a gradual tapered shape from the +Y side to the −Y side.

### (Effect of First Modification)

According to the first modification, on the −Y side of the vibrating arm portions 10 and 11, the width between the +X side surfaces 10a and 11a of the vibrating arm portions 10 and 11 and the +X side surface 51c of the groove portion 51, and the width between the −X side surfaces 10b and 11b of the vibrating arm portions 10 and 11 and the −X side surface 51d of the groove portion 51 are formed to be large. Accordingly, since the bending rigidity on the −Y side of the vibrating arm portions 10 and 11 can further be increased, vibration of the vibrating arm portions 10 and 11 in the +Z direction may be inhibited. Also, by forming the ribs 53 from the +Y side where the width of the groove portions 51 is large, the cross-sectional area of the vibrating arm portions 10 and 11 in the areas where the groove portions 51 are formed may be substantially constant in the Y direction. When the vibrating arm portions 10 and 11 are subjected to an impact, concentration of the stress is inhibited so that the breakage of the vibrating arm portions 10 and 11 is prevented.

### (Second Modification of Embodiment)

Subsequently, a second modification of the embodiment will be described.

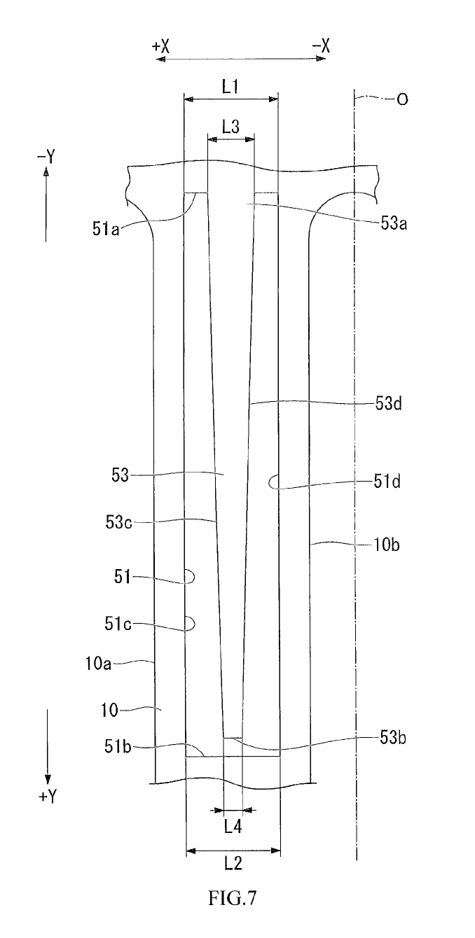

FIG. 7 is an explanatory drawing showing the second modification of the embodiment.

In the embodiment, the first modification described above, the width of the groove portions 51 is formed to be reduced from the +Y side to the −Y side (see FIG. 2 and FIG. 6). In contrast, the second modification is different from the embodiment in that the width of the groove portions 51 is formed to be constant along the Y direction. The description of the components same as the embodiment will be omitted.

### (Groove Portion)

As shown in FIG. 7, the groove portion 51 is formed on the first vibrating arm portion 10. The groove portion 51 is formed so that the width L1 of the −Y side wall surface 51a is substantially the same as the width L2 of the +Y side wall surface 51b. More specifically, from the +Y side to the −Y side, the +X side surface 51c of the groove portion 51 and the +X side surface 10a of the first vibrating arm portion 10, and the −X side surface 51d of the groove portion 51 and the −X side surface 10b of the first vibrating arm portion 10 are substantially parallel to each other. In other words, the width of the groove portions 51 is formed to be constant along the Y-direction. In the same manner as the embodiment, the width L3 of the −Y side end portion 53a of the rib 53 is larger than the width L4 of the +Y side end portion 53b of the rib 53.

### (Effect of Second Modification)

According to the second modification, by forming the width of the groove portions 51 to be constant along the Y direction of the vibrating arm portions 10 and 11, the +X side surfaces 10a and 11a of the vibrating arm portions 10 and 11 and the +X side surface 51c of the groove portion 51, and the −X side surfaces 10b and 11b of the vibrating arm portions 10 and 11 and the −X side surface 51d of the groove portion 51 may be arranged to oppose each other at very small distance. Accordingly, when a voltage is applied to the excitation electrodes 13 and 14, an electrical field intersecting the +X side surfaces 10a and 11a of the vibrating arm portions 10 and 11 and the +X side surface 51c of the groove portion 51, and the −X side surfaces 10b and 11b of the vibrating arm portions 10 and 11 and the −X side surface 51d of the groove portion 51 along the X direction may be efficiently formed. In other words, since the electrical field is efficiently formed on the vibrating arm portions 10 and 11 in the X direction, the vibrating arm portions 10 and 11 may be vibrated in the X direction efficiently. In particular, by forming the width of the ribs 53 on the −Y side to be larger than the width of the ribs 53 on the +Y side and forming the width of the groove portions 51 to be constant along the Y direction of the vibrating arm portions 10 and 11, the piezoelectric vibration reed 4 having little loss may be formed while enhancing the bending rigidity of the vibrating arm portions 10 and 11 on the −Y side.

### (Piezoelectric Vibrator)

Subsequently, a piezoelectric vibrator 1 will be described as a package 9 provided with the piezoelectric vibration reed 4 manufactured in the method of manufacturing described above.

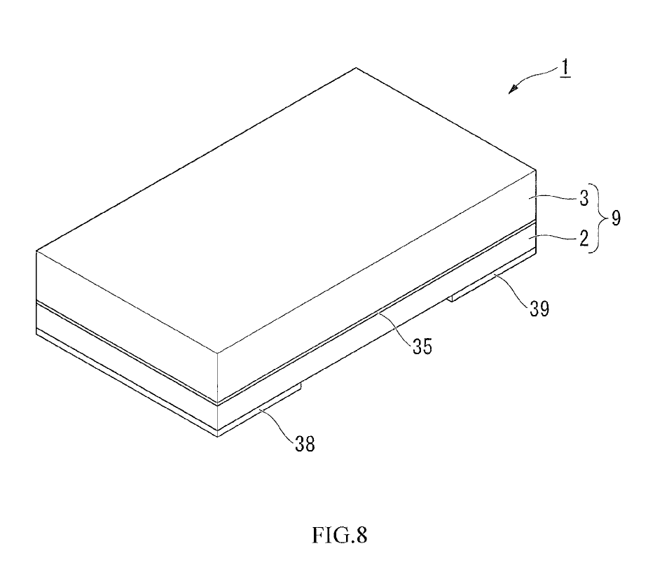

FIG. 8 is an appearance perspective view of the piezoelectric vibrator 1.

FIG. 9 is a plan view showing a configuration of the interior of the piezoelectric vibrator 1 in a state in which a lid substrate 3 is removed.

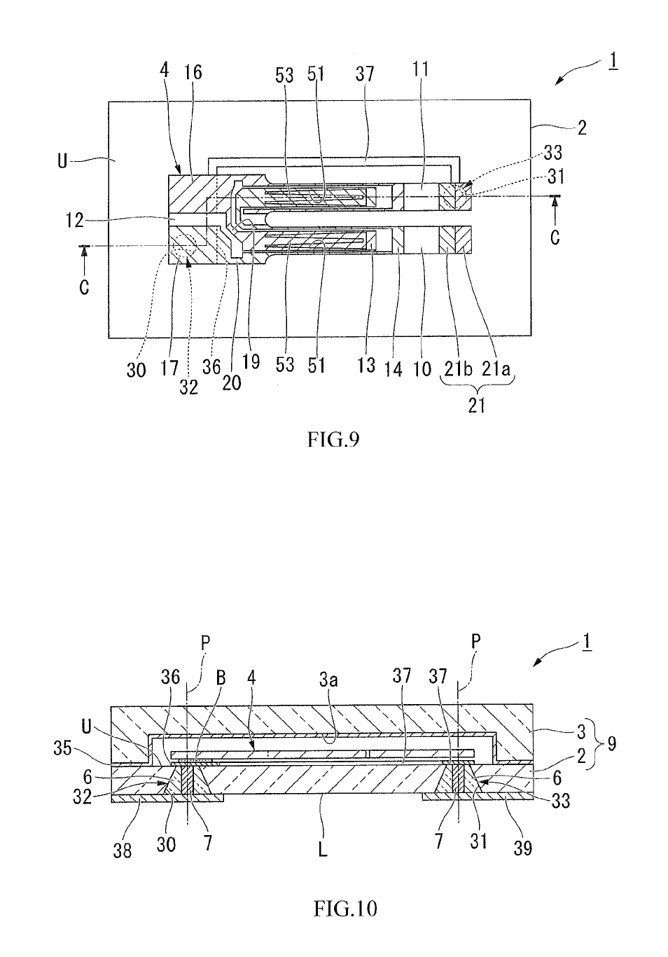

FIG. 10 is a cross-sectional view taken along the line C-C in FIG. 9.

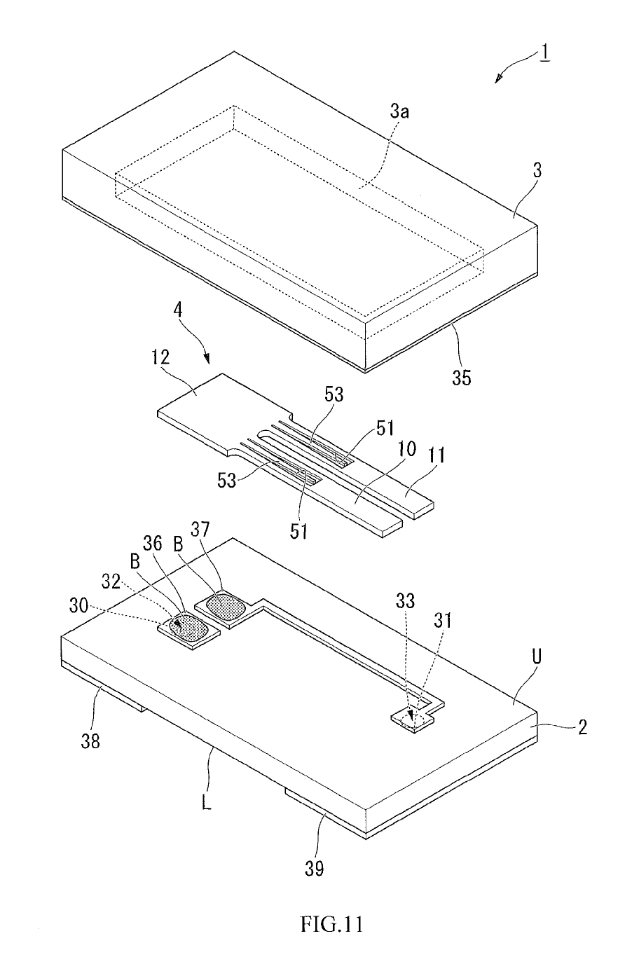

FIG. 11 is an exploded perspective view of the piezoelectric vibrator 1 shown in FIG. 8.

In FIG. 11, illustration of the excitation electrodes 13 and 14, the drawn electrodes 19 and 20, the mount electrodes 16 and 17, and the weight metal film 21 described later will be omitted for the sake of easy understanding of the drawing.

As shown in FIG. 8, the piezoelectric vibrator 1 in this embodiment is the surface-mounted piezoelectric vibrator 1 including the package 9 formed by anodic wafer bonding of a base substrate 2 and the lid substrate 3 via a bonding film 35, and the piezoelectric vibration reed 4 accommodated in a cavity 3a of the package 9.

As shown in FIG. 10, the base substrate 2 and the lid substrate 3 are anodically wafer bondable substrates formed of a glass material, for example, a soda-lime glass, and is formed into a substantially plate shape. The cavity 3a configured to accommodate the piezoelectric vibration reed 4 is formed on the side of the bonding surface of the lid substrate 3 with respect to the base substrate 2.

The entire surface of the lid substrate 3 on the side of the bonding surface with respect to the base substrate 2 is formed with the bonding film 35 (bonding material) for the anodic wafer bonding. In other words, the bonding film 35 is formed into a frame area around the cavity 3a in addition to the entire inner surface of the cavity 3a. Although the bonding film 35 in this embodiment is formed of silicone, the bonding film 35 may be formed of chrome or aluminum. The bonding film 35 and the base substrate 2 are bonded by anodic wafer bonding, and the cavity 3a is vacuumized and sealed.

The piezoelectric vibrator 1 penetrates through the base substrate 2 in the thickness direction and includes through electrodes 32 and 33 which electrically conducts an inner side of the cavity 3a and an outside of the piezoelectric vibrator 1. Then, the through electrodes 32 and 33 are arranged in through holes 30 and 31 penetrating through the base substrate 2, and each include metallic pins 7 configured to electrically connect the piezoelectric vibration reed 4 and the outside, and cylindrical members 6 to be filled into portions between the through holes 30 and 31 and the metallic pins 7. in the following description, the through electrode 32 will be described as an example. However, the through electrode 33 is also the same. The electrical connections of the through electrode 33, a drawing electrode 37, and an external electrode 38 are also the same as that of the through electrode 32, a drawing electrode 36, and an external electrode 38.

The through hole 30 is formed so that the inner diameter is gradually enlarged from an upper surface U side to a lower surface L side of the base substrate 2, and is formed to have a tapered shape in cross section including the center axis P of the through hole 30.

The metallic pins 7 are each a conductive rod-shaped member formed of a metallic material such as silver, nickel alloy, or aluminum, and is molded by forging or press work. The metallic pins 7 are preferably formed of metal having a coefficient of linear expansion close to that of glass material of the base substrate 2, for example, alloy containing 58 weight percent of iron and 42 weight percent of nickel (42 alloy).

The cylindrical member 6 is formed by sintering glass fit paste. The metallic pin 7 is arranged at the center of the cylindrical member 6 so as to penetrate through the cylindrical member 6, and the cylindrical member 6 is firmly secured to the metallic pin 7 and the through hole 30.

As shown in FIG. 11, a pair of the drawing electrodes 36 and 37 are patterned on the side of the upper surface U of the base substrate 2. Then, bumps B formed of gold or the like are formed respectively on the pair of drawing electrodes 36 and 37 and a pair of the mount electrodes of the piezoelectric vibration reed 4 are mounted using the bumps B. Accordingly, the mount electrode 17 (see FIG. 9) of the piezoelectric vibration reed 4 is in conduction with the through electrode 32 via the drawing electrode 36, and the mount electrode 16 (see FIG. 9) is in conduction with the through electrode 33 via the other drawing electrode 37.

A pair of the external electrodes 38 and 39 are formed on the lower surface L of the base substrate 2. The pair of external electrodes 38 and 39 are formed at both end portions of the base substrate 2 in the longitudinal direction, and are electrically connected respectively to a pair of through electrodes 32 and 33.

When activating the piezoelectric vibrator 1 configured in this manner, a predetermined drive voltage is applied to the external electrodes 38 and 39 formed on the base substrate 2. Accordingly, since a voltage can be applied to the first excitation electrodes 13 and the second excitation electrodes 14 of the piezoelectric vibration reed 4, the pair of vibrating arm portions 10 and 11 may be vibrated in the X direction (see FIG. 1) so as to be moved toward and away from each other at a predetermined frequency. Then, the piezoelectric vibrator 1 may be used as a time-of-day source, a timing source of a control signal or a reference signal source using the vibrations of the pair of vibrating arm portions 10 and 11.

### (Effect)

According to the embodiment, since the piezoelectric vibration reed 4 which is capable of inhibiting the increase in the CI value or the vibration leak is provided, the piezoelectric vibrator 1 presenting high efficiency with small power consumption is provided.

### (Oscillator)

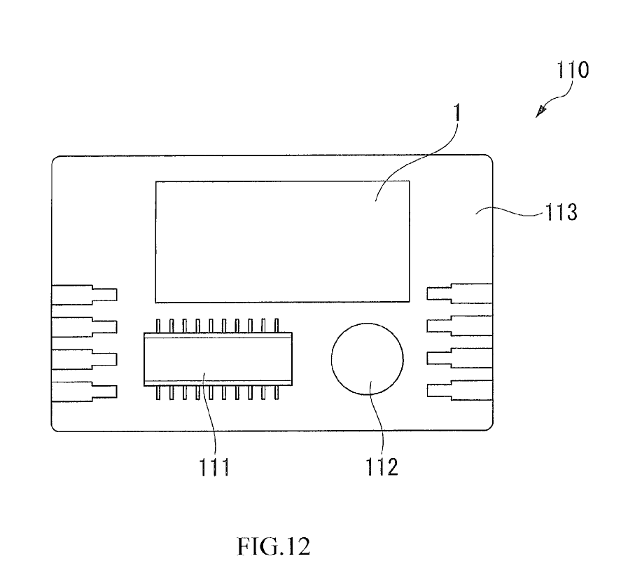

Subsequently, an embodiment of an oscillator according to the invention will be described with reference to FIG. 12.

An oscillator 110 in this embodiment includes the piezoelectric vibrator 1 configured as an oscillating element electrically connected to an integrated circuit 111 as shown in FIG. 12. The oscillator 110 includes a substrate 113 on which an electronic element component 112 such as a capacitor is mounted. The substrate 113 includes the integrated circuit 111 for the oscillator mounted thereon, and the piezoelectric vibrator 1 is mounted in the vicinity of the integrated circuit 111. The electronic element component 112, the integrated circuit 111, and the piezoelectric vibrator 1 are electrically connected respectively by a wiring pattern, not shown. The respective components are molded by a resin, not shown.

In the oscillator 110 configured in this manner, when a voltage is applied to the piezoelectric vibrator 1, the piezoelectric vibration reed in the piezoelectric vibrator 1 vibrates. Such vibrations are converted into an electric signal by the piezoelectric property of the piezoelectric vibration reed, and are input to the integrated circuit 111 as the electric signal. The input electric signal is subjected to various processes by the integrated circuit 111 and is output as a frequency signal. Accordingly, the piezoelectric vibrator 1 functions as an oscillating element.

In addition, by selectively setting the configuration of the integrated circuit 111, such as an RTC (Real Time Clock) module or the like according to the request, for example, in addition to the function of a single-function oscillator for a time piece, a function to control the date and time of operation of the single-function oscillator for a time piece or external instruments or a function to provide the time of day or a calendar may be added.

According to the embodiment, the high performance oscillator 110 presenting high efficiency with small power consumption is provided.

### (Electronic Instrument)

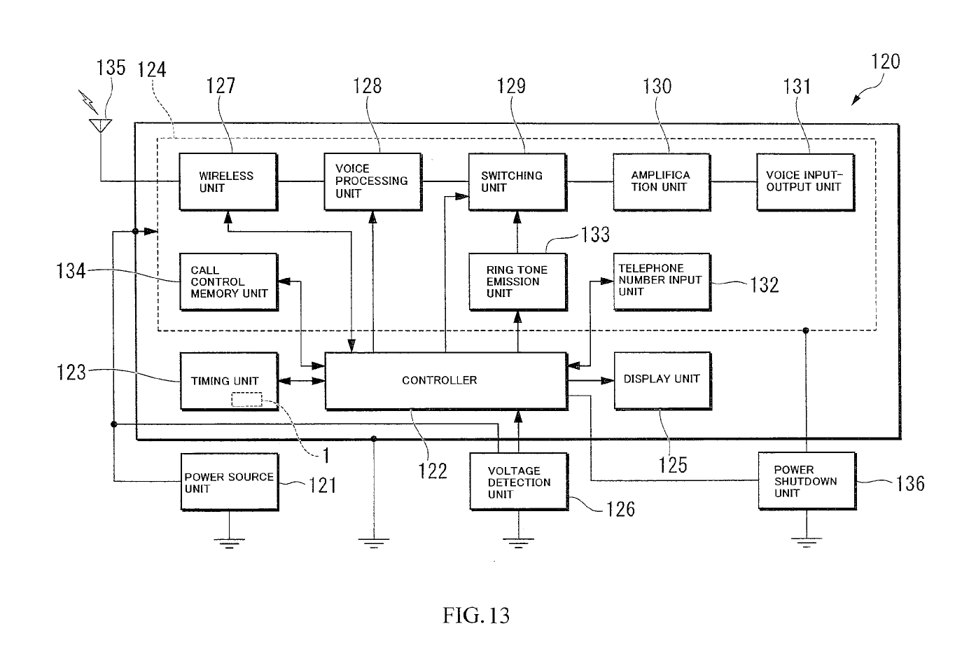

Referring now to FIG. 13, an embodiment of an electronic instrument according to the invention will be described. A portable digital assistant device 120 having the piezoelectric vibrator 1 described above as the electronic instrument will be described as an example. First of all, the portable digital assistant device 120 in this embodiment is represented, for example, by a mobile phone, which is a developed and improved wrist watch of the related art. An appearance is similar to the wrist watch, including a liquid crystal display at a portion corresponding to a dial, which is configured to display current time or the like on a screen thereof. When used as a communication instrument, the same communication as the mobile phone of the related art may be performed by removing the same from the wrist and using a speaker and a microphone integrated in a potion inside a band. However, downsizing and reduction in weight are dramatically achieved in comparison with the mobile phone of the related art.

Subsequently, a configuration of the portable digital assistant device 120 will be described. The portable digital assistant device 120 includes the piezoelectric vibrator 1 and a power source unit 121 configured to supply power as shown in FIG. 13. The power source unit 121 is formed of, for example, a lithium secondary cell. The power source unit 121 includes a control unit 122 configured to perform various types of control, a clocking unit 123 configured to count time of day or the like, a communication unit 124 configured to perform communication with the outside, a display unit 125 configured to display various items of information, and a voltage detection unit 126 configured to detect voltage of the respective functional portions connected in parallel to each other. Then, the power is supplied to the respective functional portions by the power source unit 121.

The control unit 122 controls the operation of the entire system, such as controlling the respective functional portions to perform sending and receiving of voice data, and counting and display of the current time-of-day. The control unit 122 includes a ROM in which a program is written in advance, a CPU configured to read out the program written in the ROM, a CPU configured to read out and execute the program written in the ROM, and a RAM used as a work area for the CPU.

The clocking unit 123 includes an integrated circuit having an oscillation circuit, a register circuit, a counter circuit, and an interface circuit integrated therein, and the piezoelectric vibrator 1. When a voltage is applied to the piezoelectric vibrator 1, the piezoelectric vibration reed vibrates, and the vibrations thereof are converted into an electric signal by the piezoelectric property of crystal, and are input to the oscillation circuit as the electric signal. The output of the oscillation circuit is binarized and is counted by the register circuit and the counter circuit. Then, sending and receiving of the signal with respect to the control unit 122 are performed via the interface circuit, and the current time of day, the current date, calendar information, or the like are displayed on the display unit 125.

The communication unit 124 has the same function as the mobile phones of the related art, and includes a wireless unit 127, a voice processing unit 128, a switch unit 129, an amplifying unit 130, a voice input/output unit 131, a phone number input unit 132, a ring tone generating unit 133, and a call control memory unit 134.

The wireless unit 127 performs sending and receiving of various types of data such as voice data with respect to a base station via an antenna 135. The voice processing unit 128 codes and decodes the voice signal input from the wireless unit 127 or the amplifying unit 130. The amplifying unit 130 amplifies the signal input from the voice processing unit 128 or the voice input/output unit 131 to a predetermined level. The voice input/output unit 131 includes a speaker, a microphone, or the like, and in configured to amplify a ringtone or a receiving voice, or collect a voice.

The ring tone generating unit 133 generates the ringtone according to a call from the base station. The switch unit 129 switches the amplifying unit 130 connected to the voice processing unit 128 to the ring tone generating unit 133 only at the time of incoming call, so that the ringtone generated by the ring tone generating unit 133 is output to the voice input/output unit 131 via the amplifying unit 130.

The call control memory unit 134 stores a program relating to control of incoming and outgoing call of communication. The phone number input unit 132 includes, for example, numerical keys from 0 to 9 and other keys, and is configured to input a telephone number of the called party by pushing these numerical keys or the like.

The voltage detection unit 126 detects voltage drop when the voltage applied to the receptive functional portions such as the control unit 122 by the power source unit 121 becomes lower than a predetermined value, and notifies the same to the control unit 122. The predetermined voltage value at this time is a value preset as a minimum required voltage for keeping a stable operation of the communication unit 124 and, for example, on the order of 3 V. The control unit 122 which receives the notification of the voltage drop from the voltage detection unit 126 prohibits the wireless unit 127, the voice processing unit 128, the switch unit 129, and the ring tone generating unit 133 from operating. In particular, the stop of the operation of the wireless unit 127 which consumes a large amount of power is essential. Then, the fact that the communication unit 124 is disabled due to insufficient remaining battery power is displayed on the display unit 125.

In other words, the operation of the communication unit 124 is prohibited by the voltage detection unit 126 and the control unit 122, and that effect may be displayed on the display unit 125. This display may be made by messages including characters. However, as more intuitive display, a cross mark (x) may be shown on a phone icon displayed on an upper portion of a display surface of the display unit 125.

With the provision of a power source blocking unit 136 which is capable of selectively blocking the electric power of a portion relating to the function of the communication unit 124, the function of the communication unit 124 may be stopped further reliably.

According to the embodiment, the high performance portable digital assistant device 120 presenting high efficiency with small power consumption is provided.

### (Radio Timepiece)

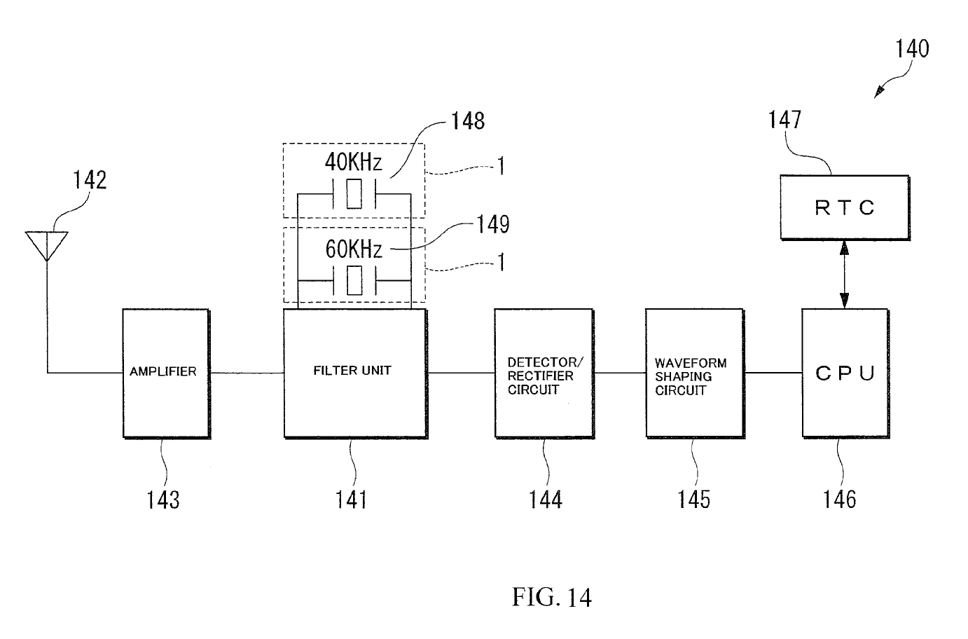

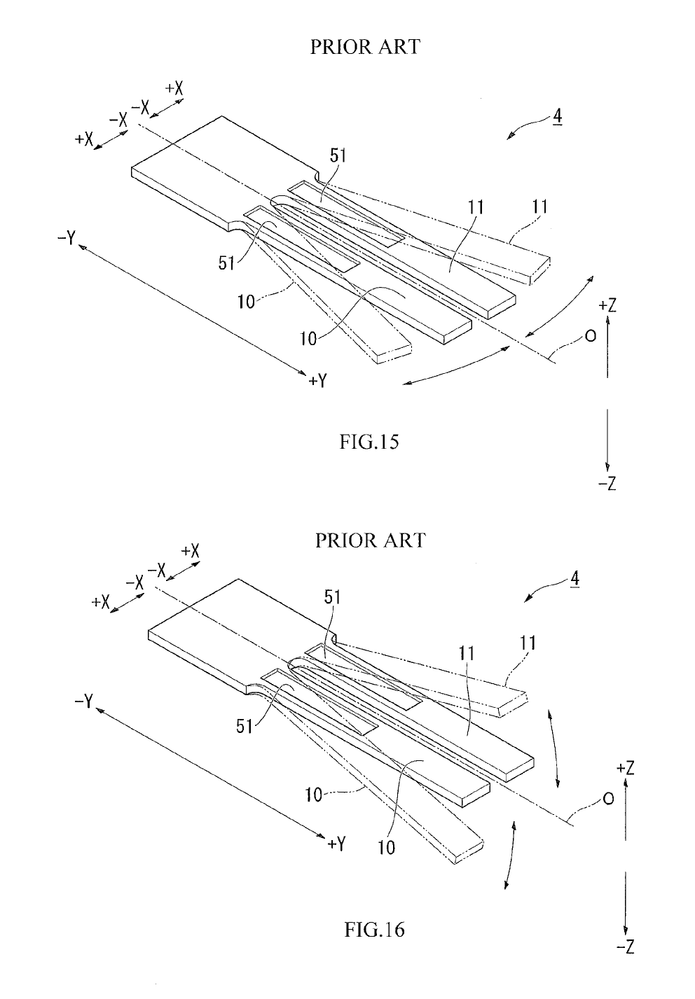

Referring now to FIG. 14, an embodiment of a radio timepiece according to the invention will be described.

A radio timepiece 140 in this embodiment includes the piezoelectric vibrator 1 electrically connected to a filter portion 141 as shown in FIG. 14, and is a timepiece having a function to receive standard radio waves including timepiece information and display correct time of day automatically corrected.

In Japan, there are transmitting stations (transmitter stations) which transmit standard radio waves in Fukushima prefecture (40 kHz) and Saga prefecture (60 kHz), and transmit respective standard radio waves. Since long waves such as 40 kHz or 60 kHz have both a property to propagate the ground surface and a property to propagate while being reverberate between an ionization layer and the ground surface, a wide range of the propagation is achieved, so that the above-described two transmitting stations cover entire part of Japan.

Hereinafter, a functional configuration of the radio timepiece 140 will be described in detail.

An antenna 142 receives a long-wave standard radio wave of 40 kHz or 60 kHz. The long standard radio wave is time information referred to as time code and subjected to an AM modulation to a carrier wave of 40 kHz or 60 kHz. The received long standard radio wave is amplified by an amplifier 143 and is filtered and synchronized by the filter portion 141 having a plurality of the piezoelectric vibrators 1.

The piezoelectric vibrators 1 in this embodiment include quartz vibrator units 148 and 149 having resonant frequencies of 40 kHz and 60 kHz which are the same as the above-described carrier frequencies, respectively.

In addition, the signal filtered and having a predetermined frequency is subjected to detection and demodulation by a detection and rectification circuit 144.

Subsequently, the time code is acquired via a waveform shaping circuit 145, and is counted by a CPU 146. The CPU 146 reads information such as the current year, day of year, day of the week, time of day, and the like. The read information is reflected on an RTC 147, and a correct time of day information is displayed.

Since the carrier wave has 40 kHz or 60 kHz, vibrators having the above-described tuning-fork-type structure are suitable for the quartz vibrator units 148 and 149.

The above-described description is based on an example in Japan, and the frequency of the long standard radio waves are different in foreign countries. For example, in Germany, a standard radio wave of 77.5 kHz is used. Therefore, when integrating the radio timepiece 140 which is compatible with the foreign countries in the portable apparatus, another piezoelectric vibrator 1 having a frequency different from that in Japan is required.

According to the embodiment, the high performance radio timepiece 140 presenting high efficiency with small power consumption is provided.

The technical scope of the invention is not limited to the embodiments shown above, and various modifications may be made without departing the scope of the invention.

For example, in the embodiment described above, the piezoelectric vibration reed 4 in the invention is employed for the surface-mounted piezoelectric vibrator 1. However, the invention is not limited thereto, and the piezoelectric vibration reed 4 in the invention may be employed for the piezoelectric vibrator of a cylinder package type, for example.

In the embodiment and the respective modifications, one each of the ribs 53 is formed in the groove portion 51. However, the number of ribs 53 is not limited to one, and a plurality of ribs 53 may be formed in the groove portion 51.

In the embodiment and the respective modifications, one each of the groove portions 51 is formed on the vibrating arm portions 10 and 11. However, the number of groove portions 51 is not limited to one, and a plurality of groove portions 51 may be formed on each of the vibrating arm portions 10 and 11.

In the embodiment and the second modification, the width of the ribs 53 formed in the groove portion 51 is formed to be increased gradually from the +Y side to the −Y side. However, for example, the rib 53 may be formed so that the width thereof is increased stepwise from the +Y side to the −Y side. Also, the rib 53 may be formed so that the width thereof is constant from the +Y side to the −Y side.

In the embodiment and the first modification, the width of the groove portions 51 is formed to be reduced from the +Y side to the −Y side in a tapered shape. However, the groove portion 51 may be formed so that the width is reduced stepwise, or example.

1. A piezoelectric vibration reed comprising:
a pair of vibrating arm portions arranged side by side extending in a longitudinal direction and having opposing main surfaces;
a base portion connecting the pair of vibrating arm portions at a proximal end thereof; and
groove portions in the opposing main surfaces of the vibrating arm portions and extending in the longitudinal direction of the vibrating arm portions, the groove portions located in an interior area of the vibrating arm portions and each having a rib extending in the longitudinal direction from a proximal sidewall surface or a distal sidewall wall surface of the groove portion toward the other one of the proximal sidewall surface and the distal sidewall surface.

2. The piezoelectric vibration reed according to claim 1, wherein the ribs extend from the proximal sidewall surface toward the distal sidewall surface.

3. The piezoelectric vibration reed according to claim 1, wherein the width of the ribs in a direction perpendicular to the longitudinal direction is larger at the proximal end the vibrating arm portions than at a distal end of the vibrating arm portions.

4. The piezoelectric vibration reed according to claim 1, wherein the width of the ribs in a direction perpendicular to the longitudinal direction is smaller at the proximal end the vibrating arm portions than at a distal end of the vibrating arm portions.

5. The piezoelectric vibration reed according to claim 1, wherein the width of the groove portions in a direction perpendicular to the longitudinal direction is constant along the longitudinal direction of the vibrating arm portions.

6. The piezoelectric vibration reed according to claim 1, wherein the width of the groove portions in a direction perpendicular to the longitudinal direction is larger at the proximal end the vibrating arm portions than at a distal end of the vibrating arm portions.

7. The piezoelectric vibration reed according to claim 1, wherein the width of the groove portions in a direction perpendicular to the longitudinal direction is smaller at the proximal end the vibrating arm portions than at a distal end of the vibrating arm portions.

8. A piezoelectric vibrator including the piezoelectric vibration reed of claim 1.

9. An oscillator including the piezoelectric vibrator of claim 8, wherein the piezoelectric vibrator is electrically connected to an integrated circuit.

10. An electronic instrument including the piezoelectric vibrator of claim 8, wherein the piezoelectric vibrator is electrically connected to a clocking unit.

11. A radio timepiece including the piezoelectric vibrator of claim 8, wherein the piezoelectric vibrator is electrically connected to a filter portion.
